(19) United States
(12) Patent Application Publication
(10) Pub. No.: US 2009/0134408 A1
(43) Pub. Date: May 28, 2009

(54) LIGHT EMITTING DIODE PACKAGE, METHOD OF FABRICATING THE SAME AND BACKLIGHT ASSEMBLY INCLUDING THE SAME

(75) Inventors: Se-Ki PARK, Suwon-si (KR); Eun-Jeong KANG, Cheonan-si (KR); Gi-Cherl KIM, Yongin-si (KR); Moon-Hwan CHANG, Cheonan-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/243,589

(22) Filed: Oct. 1, 2008

(30) Foreign Application Priority Data
Nov. 28, 2007 (KR) 10-2007-0122108

(51) Int. Cl. H01L 33/00; H01L 21/50

(52) U.S. Cl. 257/88; 438/26; 257/E33.056; 257/E21.499

(57) ABSTRACT

A light emitting diode (“LED”) package includes: a mold including an accommodating groove formed therein and which includes a side surface and a bottom surface; an electrode pattern disposed on the bottom surface; a plurality of LED chips disposed on the electrode pattern; and protective resin disposed in the accommodating groove. A center LED chip of the plurality of LED chips is disposed at a center of the bottom surface, and a height of the center LED chip above the bottom surface is greater than heights of other LED chips of the plurality of LED chips above the bottom surface.

This application claims priority to Korean Patent Application No. 10-2007-0122108, filed on Nov. 28, 2007, and all the benefits accruing therefrom under 35 U.S.C. §119, the contents of which in its entirety are herein incorporated by reference.

### BACKGROUND OF THE INVENTION

1. Field of the Invention

The present invention relates to a light emitting diode (“LED”) package, a method of fabricating the LED package and a backlight assembly including the LED package, and more particularly, to an LED package having improved thermal resistance and resistance to moisture infiltration, a method of fabricating the LED package, and a backlight assembly including the LED package.

2. Description of the Related Art

Liquid crystal displays (“LCDs”) are a widely-used type of flat panel display (“FPD”). An LCD typically includes two substrates, on which electrodes are formed, and a liquid crystal layer interposed between the two substrates. The LCD applies a voltage to the electrodes, thereby creating an electric field between the two substrates. The electric field aligns liquid molecules in the liquid crystal layer and thus controls an amount of light passing through the liquid crystal layer to display a desired image.

The LCD is not self-luminous, and therefore requires a backlight assembly which emits light to pass through the liquid crystal layer and display the desired image. Examples of light sources used for the backlight assembly include cold cathode fluorescent lamps (“CCFLs”), external electrode fluorescent lamps (“EEFLs”) and light emitting diodes (“LEDs”), for example. Recently, demand for backlight assemblies using LEDs, and high luminance LEDS in particular, is increasing.

LEDs used for the backlight assembly may be package-type LEDs. Specifically, LED packages are arranged on an arrangement plate and are used as light sources for the LCD. More specifically, each LED package includes a mold having LED chips mounted thereon. The mold is covered with a protective resin. However, when the LED packages are exposed to high temperature and/or when moisture seeps into the LED package, e.g., between the mold and the protective resin, a yellowing phenomenon occurs. In addition, the protective resin may become separated from the mold. Furthermore, wires connecting the LED chips may be disconnected.

### BRIEF SUMMARY OF THE INVENTION

An exemplary embodiment of the present invention provides a light emitting diode (“LED”) package having improved thermal resistance and wetproofness, e.g., resistance to moisture infiltration.

An alternative exemplary embodiment of the present invention provides a method of fabricating the LED package.

An alternative exemplary embodiment of the present invention provides a backlight assembly including the LED package.

According to an exemplary embodiment of the present invention, an LED package includes: a mold having an accommodating groove formed therein and which includes a side surface and a bottom surface; an electrode pattern disposed on the bottom surface; a plurality of LED chips disposed on the electrode pattern; and protective resin disposed in the accommodating groove. A center LED chip of the plurality of LED chips is disposed at a center of the bottom surface, and a height of the center LED chip above the bottom surface is greater than heights of other LED chips of the plurality of LED chips above the bottom surface.

According to an alternative exemplary embodiment of the present invention, a method of fabricating an LED package includes: forming an accommodating groove in a mold; forming a bottom surface and a side surface in the accommodating groove; forming an electrode pattern on the bottom surface; disposing a center LED chip on the electrode pattern in a center of the bottom surface; disposing a side LED chip on the electrode pattern; and disposing a protective resin in the accommodating groove. A height of the center LED chip is above the bottom surface is greater than a height of the side LED chip above the bottom surface.

According to another alternative exemplary embodiment of the present invention, a backlight assembly includes a first container, an arrangement plate disposed in the first container, and an LED package. The LED package includes a mold including an accommodating groove formed therein and which includes a side surface and a bottom surface, an electrode pattern disposed on the bottom surface, a plurality of LED chips disposed on the electrode pattern, and protective resin disposed in the accommodating groove. A center LED chip of the plurality of LED chips is disposed at a center of the bottom surface, and a height of the center LED diode chip is greater than heights of other LED chips of the plurality of LED chips above the bottom surface.

### BRIEF DESCRIPTION OF THE DRAWINGS

The above and other aspects, features and advantages of the present invention will become more readily apparent by describing in further detail exemplary embodiments thereof with reference to the accompanying drawings, in which:

FIG. 1 is a side perspective view of a light emitting diode (“LED”) package according to an exemplary embodiment of the present invention;

FIG. 2 is a cutout side perspective view of the LCD package according to the exemplary embodiment of the present invention shown in FIG. 1;

FIG. 3 is a partial cross-sectional view taken along line A-A′ of FIG. 1;

FIG. 4 is a top plan view of the LED package according to the exemplary embodiment of the present invention shown in FIG. 1;

FIG. 5 is a side perspective view of an LED package according to an alternative exemplary embodiment of the present invention;

FIG. 6 is a cutout side perspective view of the LED package according to the exemplary embodiment of the present invention shown in FIG. 5;

FIGS. 7A through 7F are partial cross-sectional views sequentially showing steps included in a method of fabricating an LED package according to an exemplary embodiment of the present invention;

FIG. 8A is a picture showing a surface of a mold of an LED package fabricated using the method according to the exemplary embodiment shown in FIGS. 7A through 7F;

FIG. 8B is a picture showing a surface of a mold of an LED package fabricated using a fabrication method according to an alternative exemplary embodiment;

FIG. 9A is a graph of distance versus height showing a measured surface profile of the mold using the method according to the exemplary embodiment shown in FIG. 8A;

FIG. 9B is a graph of distance versus height showing a measured surface profile of the mold of fabricated using the method according to the alternative exemplary embodiment shown in FIG. 8B;

FIG. 10 is an exploded perspective view of a backlight assembly according to an exemplary embodiment of the present invention; and

FIG. 11 is an exploded perspective view of a backlight assembly according to an alternative exemplary embodiment of the present invention.

### DETAILED DESCRIPTION OF THE INVENTION

The invention will now be described more fully hereinafter with reference to the accompanying drawings, in which exemplary embodiments of the invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including,” when used in this specification, specify the presence of stated features, regions, integers, steps, operations, elements and/or components, but do not preclude the presence or addition of one or more other features, regions, integers, steps, operations, elements, components and/or groups thereof.

Furthermore, relative terms, such as “lower” or “bottom” and “upper” or “top” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on the “upper” side of the other elements. The exemplary term “lower” can, therefore, encompass both an orientation of “lower” and “upper,” depending upon the particular orientation of the figure. Similarly, if the device in one of the figures were turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning which is consistent with their meaning in the context of the relevant art and the present disclosure, and will not be interpreted in an idealized or overly formal sense unless expressly so defined herein.

Exemplary embodiments of the present invention are described herein with reference to cross section illustrations which are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes which result, for example, from manufacturing. For example, a region illustrated or described as flat may, typically, have rough and/or nonlinear features. Moreover, sharp angles which are illustrated may be rounded. Thus, the regions illustrated in the figures are schematic in nature and their shapes are not intended to illustrate the precise shape of a region and are not intended to limit the scope of the present invention.

Hereinafter, exemplary embodiments of the present invention will be described in further detail with reference to the accompanying drawings. Specifically, a light emitting diode (“LED”) package according to an exemplary embodiment of the present invention will now be described in further detail with reference to the accompanying drawings.

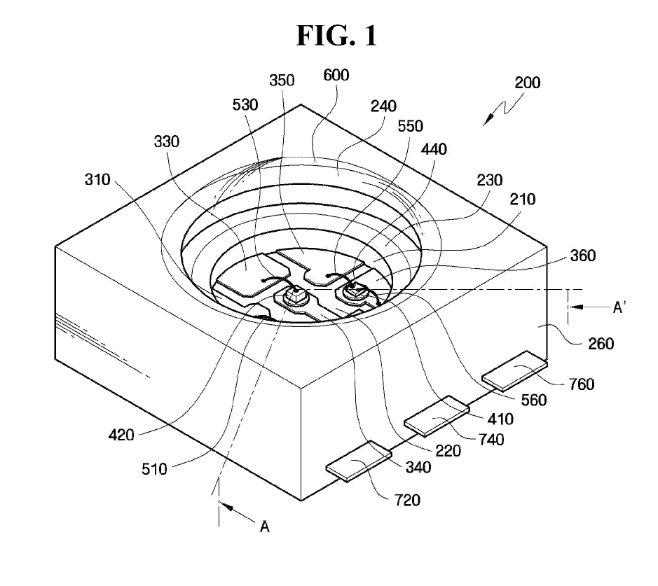

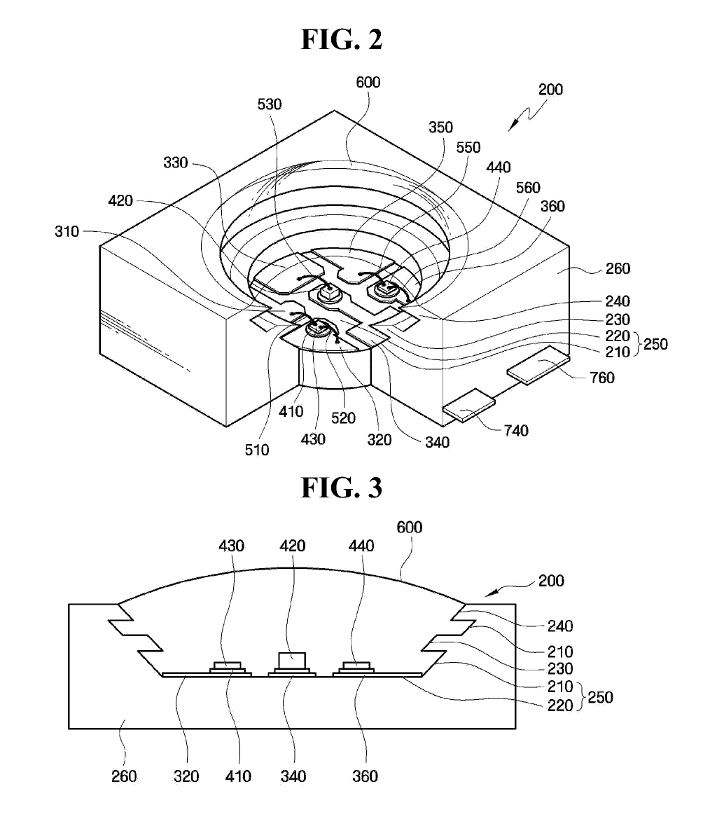

FIG. 1 is a side perspective view of an LED package according to an exemplary embodiment of the present invention. FIG. 2 is a cutout side perspective view of the LCD package according to the exemplary embodiment of the present invention shown in FIG. 1.

Referring to FIGS. 1 and 2, an LED package 200 includes a mold 260 having an accommodating groove 250, one or more LED chips, e.g., a first LED chip 420, a second LED chip 430 and a third LED chip 440, mounted in the accommodating groove 250, protective resin 600 disposed over the accommodating groove 250, and a first protrusion 230 which prevents the protective resin 600 from detaching from, e.g., separating from, the mold 260.

Specifically, the accommodating groove 250 is formed in the mold 260. To protect the first LED chip 420, the second LED chip 430 and the third LED chip 440 mounted in the accommodating groove 250, the mold 260 is made of a polymer resin, and, in particular, a hard polymer resin. For example, the mold 260 may be made of polyphthalamide (“PPA”), but alternative exemplary embodiments are not limited thereto.

The accommodating groove 250 includes a side surface 210 and a bottom surface 220. In an exemplary embodiment, the accommodating groove 250 may be shaped like a cup, as shown in FIGS. 1 through 3. Further, a cross section of the accommodating groove 250 may become wider from the bottom surface 220 toward a top opening thereof. In addition, the side surface 210 of the accommodating groove 250 may include an inclined plane.

The first protrusion 230 protrudes from the side surface 210 of the accommodating groove 250, and prevents the protective resin 600 from detaching, e.g., separating, from the mold 260, and, more specifically, from the accommodating groove 250, as will be described in greater detail below.

In an exemplary embodiment, the first protrusion 230 may be separated from the bottom surface 220 by a gap having a predetermined height to allow the protective resin 600 to flow between the bottom surface 220 and the first protrusion 230, e.g., in the gap. Further, the first protrusion 230 may extend from the side surface 210 substantially parallel to the bottom surface 220. Thus, the protective resin 600 is fixed by the first protrusion 230, and cannot be detached upward from the mold 260. In addition, the first protrusion 230 may be formed on a whole surface of the side surface 210 along a circumferential direction of the side surface 210.

In an alternative exemplary embodiment, an additional protrusion 240, e.g., a second protrusion 240, may be formed on the side surface 210 of the accommodating groove 250 to further prevent the protective resin 600 from detaching from the mold 260, e.g., to more securely fix the protective resin 600 to the accommodating groove 250, as shown in FIGS. 1 through 3. The protrusion 240 may be substantially parallel to the bottom surface 220, similar to as described above with respect to the first protrusion 230. The first protrusion 230 and the additional protrusion 240 may be separated from each other by a gap to allow the protective resin 600 to be flow between them. A distance between the additional protrusion 240 and the bottom surface 220 may be different from a distance between the first protrusion 230 and the bottom surface 220. Specifically, the distance between the additional protrusion 240 and the bottom surface 220 may be greater than the distance between the first protrusion 230 and the bottom surface 220, as best shown in FIG. 3. Further, the additional protrusion 240 may also be formed on the entire surface of the side surface 210 along the circumferential direction of the side surface 210. Since the first protrusion 230 and the additional protrusion 240 fix the protective resin 600 to the accommodating groove 250, the protective resin 600 does not slip out of the accommodating groove 250 even when moisture seeps into the accommodating groove 250, such as under high-temperature and high-humidity conditions, for example. In an exemplary embodiment, the first protrusion 230 and the additional protrusion on the side surface are formed on the side surface 210. However, the present invention is not limited thereto. For example, the first protrusion 230 or the additional protrusion 240 may be formed on the side surface 210.

The mold 260 will now be described in further detail with reference to FIGS. 2 and 3. FIG. 3 is a partial cross-sectional view taken along line A-A′ of FIG. 1.

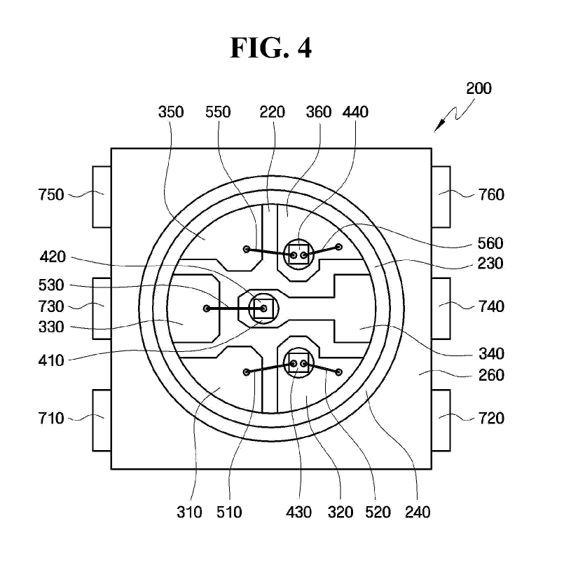

Referring to FIGS. 2 and 3, a plurality of electrode patterns 310 through 360 are formed on the bottom surface 220. The electrode patterns 310 through 360 may be formed by coating a material having sufficient conductivity, such as silver (Ag), for example, on the bottom surface 220. In an exemplary embodiment, the plurality of electrode patterns 310 through 360 patterned on the bottom surface 220 is divided into positive electrode patterns 320, 340 and 360 and negative electrode patterns 310, 330 and 350. To receive power from an external source (not shown), the positive electrode patterns 320, 340 and 350 are connected to positive electrode terminals 720, 740 and 760 (see FIG. 1), respectively, while the negative electrode patterns 310, 330 and 350 are connected to negative electrode terminals 710, 730 and 750 (see FIG. 4), respectively.

One or more LED chips, e.g., the first LED chip 420, the second LED chip 430 and the third LED chip 440, are mounted on the plurality of electrode patterns 310 through 360 More specifically, the first LED chip 420, the second LED chip 430 and the third LED chip 440 are mounted on the positive electrode patterns 340, 320 and 360, respectively, using paste 410, as shown in FIG. 4. The paste 410 may be, for example, silicon paste which substantially reduces and/or effectively prevents a yellowing phenomenon.

An arrangement of components of the LED package 200 will now be described in further detail with reference to FIG. 4. FIG. 4 is a top plan view of the LED package according to the exemplary embodiment of the present invention shown in FIG. 1.

Referring to FIG. 4, the first LED chip 420, the second LED chip 430 and the third LED chip 440 are die-bonded onto the paste 410. A single LED chip representing white or, alternatively, a plurality of LED chips may be used as the first LED chip 420, the second LED chip 430 and/or the third LED chip 440. The first LED chip 420, the second LED chip 430 and the third LED chip 440 are not be electrically connected to one another and may be die-bonded onto the positive electrode patterns 320, 340 and 360, respectively, as shown in FIG. 4.

In the LED package 200 according to an exemplary embodiment, the first LED chip 420 is formed at a center of the bottom surface 220 of the accommodating groove 250 (see FIG. 3). Specifically, the first LED chip 420 is a vertical electrode type LED chip, and is therefore taller than the second LED chip 430 and the third LED chip 440, which are both a horizontal electrode type LED chip. In addition, the first LED chip 420 is connected to a single wire 530, whereas the second LED chip 430 and the third LED chip 440 are connected to a pair of wires 510 and 520 and a pair of wires 550 and 560, respectively. Since the first LED chip 420 is taller than the second LED chip 430 and the third LED chip 440, it can be damaged more easily. Thus, the first LED chip 420 is mounted at the center of the bottom surface 220 of the accommodating groove 250 in an exemplary embodiment. Consequently, the first LED chip 420 prevented from being damaged if protective resin (not shown) detaches from the accommodating groove 250 due to permeation of moisture into the accommodating groove 250. In addition, the wire 530 connected to the first LED chip 420 is thereby prevented from being disconnected.

In an exemplary embodiment, the first LED chip 420 is a red LED chip which emits red light, and the second LED chip 430 and/or the third LED chip 440 may be green LED chip which emits a green lights and a blue LED chip which emits a blue light, respectively.

The first LED chip 420, the second LED chip 430 and the third LED chip 440 are mounted on the plurality of electrode patterns 310 through 360, and the plurality of electrode patterns 310 through 360 are connected to a plurality of electrode terminals 710 through 760, e.g., the positive electrode terminals 720, 740 and 760 and the negative electrode terminals 710, 730 and 750, respectively, to receive power from the external source (not shown). When receiving power from the external source via the plurality of electrode patterns 310 through 360, the first LED chip 420, the second LED chip 430 and the third LED chip 440 emit light.

The wires 510 through 560 are bonded to the first LED chip 420, the second LED chip 430 and the third LED chip 440 and electrically connect the first LED chip 420, the second LED chip 430 and the third LED chip 440 to the plurality of electrode patterns 310 through 360. As described above, the first LED chip 420 is a vertical electrode type LED and is connected to the wire 530. However, the second LED chip 430 and the third LED chip 440 are horizontal electrode type LEDs and are connected to the pair of wires 510 and 520 and the pair of wires 550 and 560, respectively.

The protective resin 600 fills the accommodating groove 250 to protect the first LED chip 420, the second LED chip 430 and the third LED chip 440. The protective resin 600 may be made of a light-transmissive material which adheres to the mold 260, such as silicon, for example, but alternative exemplary embodiments are not limited thereto. The protective resin 600 fills the accommodating groove 250 to a level substantially equal to a height of the mold 260. Alternatively, the protective resin 600 may fill the accommodating groove 250 to a level higher than the height of the mold 260 and protrude from the mold 260 in a dome shape, as best shown in FIG. 3.

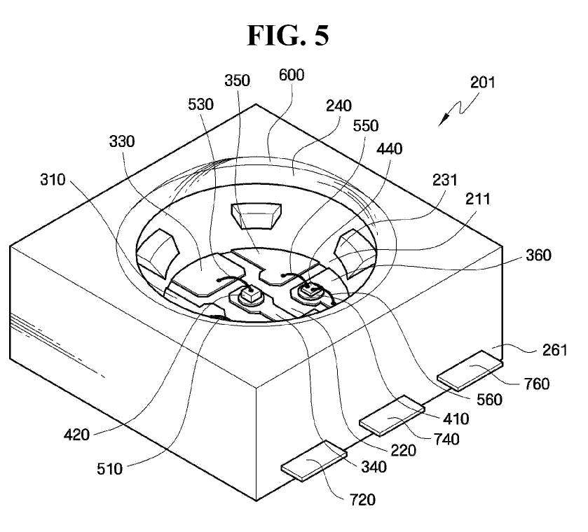

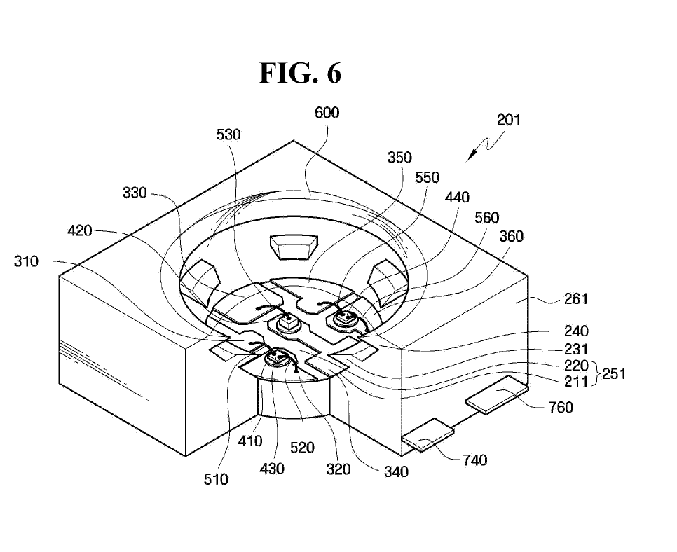

Hereinafter, an LCD package according to an exemplary embodiment of the present invention will be described in further detail with reference to FIGS. 5 and 6. FIG. 5 is a side perspective view of an LED package according to an alternative exemplary embodiment of the present invention. FIG. 6 is a cutout side perspective view of the LED package according to the alternative exemplary embodiment of the present invention shown in FIG. 5. The same reference characters refer to the same or like components between FIGS. 1 through 4 and FIGS. 5 and 6; therefore, any repetitive description thereof will hereinafter be omitted. It will be noted that a shape of a protrusion and/or an additional protrusion in the LED package according to the alternative exemplary embodiment shown in FIGS. 5 and 6 is different from that of the first protrusion 230 and the additional protrusion 240 in the LED package 200 according to the exemplary embodiment of the present invention shown in FIGS. 1 through 4.

Referring to FIGS. 5 and 6, an LED package 201 according to an alternative exemplary embodiment of the present invention includes a mold 261 having an accommodating groove 251 formed therein. A plurality of protrusions 231 are formed on a side surface 211 of the accommodating groove 251 along an inner circumference of the side surface 211. Protrusions 231 of the plurality of protrusions 231 are separate from each other. Specifically, while the first protrusion 230 according to the exemplary embodiment shown in FIGS. 1 and 2 is continuously formed on the side surface 210 along the inner circumference of the side surface 210, e.g., the first protrusion 230 is contiguous, the protrusions 231 according to the exemplary embodiment shown in FIGS. 5 and 6 are not contiguous, e.g., are formed on the side surface 211 along the inner circumference of the side surface 211 are separate from each other. Hence, portions of the side surface 211 between the protrusions 231 are exposed in the exemplary embodiment shown in FIGS. 5 and 6.

However, in an exemplary embodiment, an additional protrusion 240 is formed on an entire surface of the side surface 211 along another inner circumference of the side surface 211, as shown in FIGS. 5 and 6. However, alternative exemplary embodiments of the present invention are not limited thereto. For example, the additional protrusion 240 may be one formed as one or more protrusions formed on the side surface 211, e.g., the additional protrusion 240 may be substantially the same as the protrusions 231. In this case, locations of the protrusions 231 and additional protrusions 240 may overlap or, alternatively, may be disposed in an alternating fashion. Further, the protrusions 231 and/or the additional protrusions 240 may have various shapes and may be formed at various locations to prevent protective resin 600 from detaching from the accommodating groove 251.

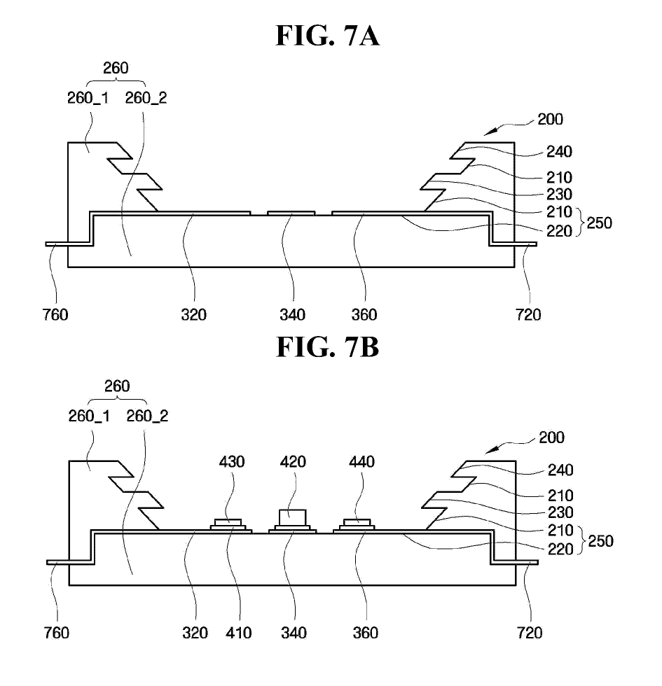

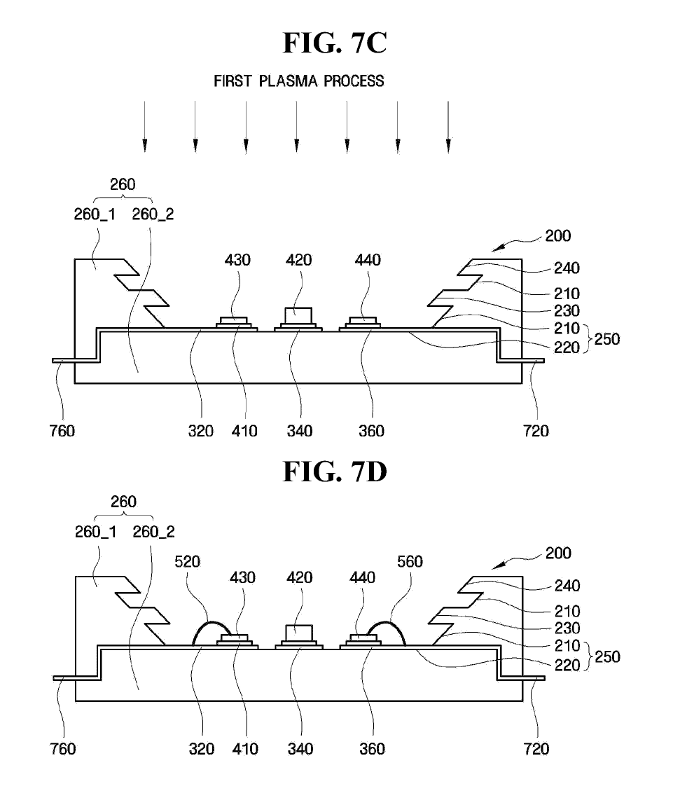

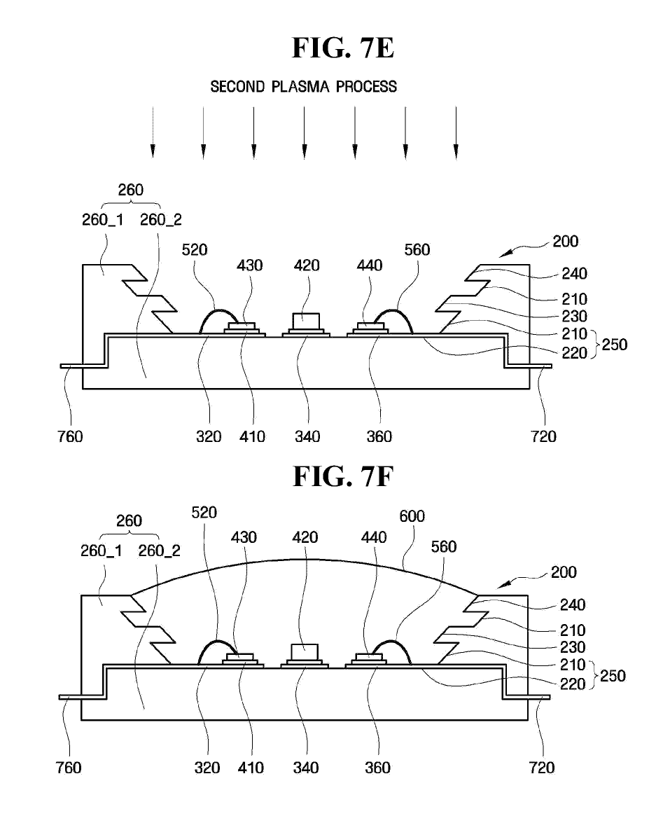

Hereinafter, a method of fabricating an LCD package according to an exemplary embodiment of the present invention will be described with reference to FIGS. 2 and 7A through 7F. FIGS. 7A through 7F are partial cross-sectional views sequentially showing steps included in a method of fabricating an LED package according to an exemplary embodiment of the present invention. Both the LED package 200 and the LED package 201 according to the exemplary embodiments of the present invention described above with reference to FIGS. 1 and 2 and FIGS. 5 and 6, respectively, may be fabricated using the fabrication method according to the exemplary embodiment hereinafter described with reference to FIGS. 2 and 7A through 7F. For purposes of discussion, however, a method for fabricating the LED package 200 according to the exemplary embodiment shown in FIG. 1 will be described as an example, but alternative exemplary embodiments are not limited thereto. In addition, the same reference characters in FIGS. 7A through 7F refer to the same or like components in FIG. 2, and any repetitive detailed description thereof will hereinafter be omitted.

Referring to FIGS. 2 and 7A, the mold 260 having the accommodating groove 250 is divided. Specifically, the mold 260 is divided into an upper portion 260_1 and a lower portion 260_2. The bottom surface 220 of the accommodating groove 250 is formed in the lower portion 260_2 of the mold 260, and the side surface 210 of the accommodating groove 265 is formed in the upper portion 260_1 of the mold 260, as shown in FIG. 7A. The first protrusion 230 and the additional protrusion 240 are formed in the upper portion 260_1 of the mold 260 to prevent the protective resin 600 from detaching from the mold 260, as described in greater detail above.

Next, the plurality of electrode patterns 310 through 360 is formed. The plurality of electrode patterns 310 through 360 may be formed by coating a conductive material, such as Ag, for example, on the lower portion 260_2 of the mold 260. More specifically, a respective pair electrode patterns 310 and 320, 330 and 340, or 350 and 360 of the plurality of electrode patterns 310 through 360 is formed for the first LED chip 420, the second LED chip 430 and the third LED chip 440, which will be mounted thereon, so that the first LED chip 420, the second LED chip 430 and the third LED chip 440 can be connected to the positive electrode patterns 340, 320 and 360, respectively, and to the negative electrode patterns 330, 310 and 350, respectively. In this case, electrode terminals (not shown) connected to the plurality of electrode patterns 310 through 360 protrude from the mold 260 to connect the plurality of electrode patterns 310 through 360 to an external power source (not shown). After the plurality of electrode patterns 310 through 360 are formed, the upper portion 260_1 is combined with the lower portion 260_2 to form the mold 260.

Referring to FIGS. 2 and 7B, one or more LED chips, e.g., the first LED chip 420, the second LED chip 430 and the third LED chip 440, are die-bonded onto the plurality of electrode patterns 310 through 360. More specifically, the first LED chip 420, the second LED chip 430 and the third LED chip 440 are mounted on the plurality of electrode patterns 310 through 360 using the paste 410. In an exemplary embodiment, the first LED chip 420, the second LED chip 430 and the third LED chip 440, which are not electrically connected to each other, may be mounted on, for example, the positive electrode patterns 340, 320 and 360, respectively, using the paste 410. In addition, the first LED chip 420 is a vertical electrode type LED chip and is therefore taller than the second LED chip 430 and the third LED chip 440, as described in greater detail above.

Referring now to FIGS. 2 and 7C, the mold 260 having the first LED chip 420, the second LED chip 430 and the third LED chip 440 is placed in a vacuum chamber (not shown), and a first plasma process is performed on the mold 260 using, for example, an Argon (Ar) gas. As a result, foreign matter on the first LED chip 420, the second LED chip 430 and the third LED chip 440 and the plurality of electrode patterns 310 through 360 is removed, which, in turn, enhances bonding capabilities of the first LED chip 420, the second LED chip 430 and the third LED chip 440 and the plurality of electrode patterns 310 through 360 in a subsequent wire-bonding process.

Referring to FIGS. 2 and 7D, the first LED chip 420, the second LED chip 430 and the third LED chip 440 are wire-bonded to the plurality of electrode patterns 310 through 360. More specifically, the first LED chip 420 including the vertical electrode type LED chip is connected to the electrode pattern 330 with the wire 530. In addition, the second LED chip 430 and the third LED chip 440, each including a horizontal electrode type LED chip, are connected to the positive electrode patterns 320 and 360 with the wires 520 and 560, respectively, and to the negative electrode patterns 310 and 350 with the wires 510 and 550, respectively.

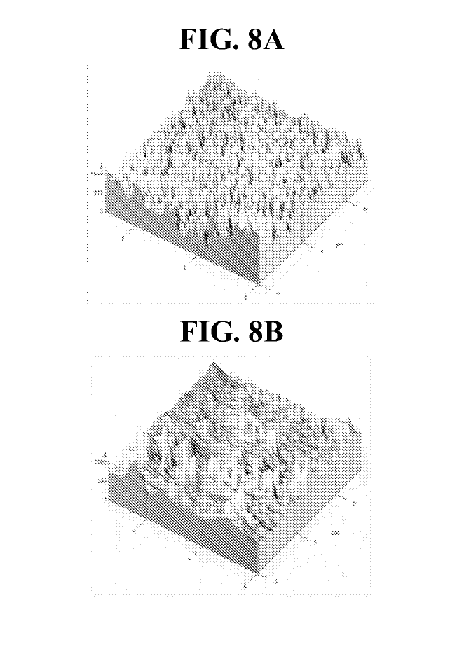

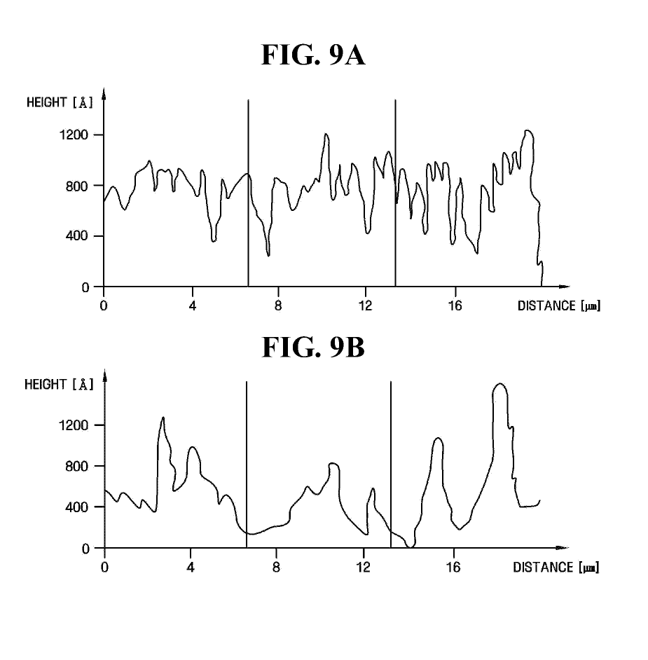

Referring to FIGS. 2 and 7E, a second plasma process using a gas such as Ar, for example, is performed on the accommodating groove 250 on which the wire-bonded first LED chip 420, the second LED chip 430 and the third LED chip 440 are mounted. As a result, foreign matter is removed from the accommodating groove 250. Consequently, in an exemplary embodiment, the protective resin 600 is attached to the mold 260 and the accommodating groove 250 securely. The second plasma process may be performed using the Ar gas from the first plasma process, but alternative exemplary embodiments of the present invention are not limited thereto. The vacuum chamber and the gas used in the first plasma process can also be used in the second plasma process, and a processing time and costs are thereby substantially reduced and/or effectively minimized in an exemplary embodiment. Further, the first plasma process and the second plasma process improve adhesion of the protective resin 600 to the mold 260 and therefor reduce a probability of the protective resin 600 from detaching from the mold 260 due to moisture which has seeped into the accommodating groove 250, for example. Specific effects of the second plasma process will be described in further detail below with reference to FIGS. 8A through 9B.

Referring now to FIGS. 2 and 7F, the accommodating groove 250 is filled with the protective resin 600. The protective resin 600 may be made of silicon, for example, but alternative exemplary embodiments are not limited thereto. The protective resin 600 is securely fixed to the accommodating groove 250 by the first protrusion 230 and/or the additional protrusion 240, and a probability of the protective resin 600 detaching from the accommodating groove 250 under high-temperature and/or high-humidity conditions is thereby substantially reduced in an exemplary embodiment of the present invention.

Performance specifications of the LED package 200 fabricated using a fabrication method according to an exemplary embodiment of the present invention will now be described in further detail with reference to FIGS. 8A through 9B. FIG. 8A is a picture showing a surface of a mold 260 of an LED package 200 fabricated using the method according to the exemplary embodiment shown in FIGS. 7A through 7F. FIG. 8B is a picture showing a surface of a mold of an LED package fabricated using a fabrication method according to an alternative exemplary embodiment. FIG. 9A is a graph of distance verses height showing a measured surface profile of the mold 260 according to the exemplary embodiment shown in FIG. 8A. FIG. 9B is a graph of distance versus height showing a measured surface profile of the mold of the alternative exemplary embodiment shown FIG. 8B.

More specifically, FIGS. 8A and 9A are a picture and a graph, respectively, showing a surface of the mold 260 of the LED package 200 fabricated using the fabrication method which includes the second plasma process, as described in greater detail above. On the other hand, FIGS. 8B and 9B are a picture and a graph, respectively, showing a surface of the mold of the LED package fabricated using a fabrication method according to an alternative exemplary embodiment which does not include the second plasma process. In FIGS. 8A and 8B, horizontal and vertical directions indicate distances, in micrometers (“μm”), of the surface of a mold, while height is shown, in angstroms (“Å”), of the mold at corresponding locations on the surface of the mold.

Referring to FIG. 8A, the height of the mold 260 of the LED package 200 fabricated using the method according to an exemplary embodiment of the present invention which includes the second plasma process is uniform across the surface thereof, as compared to FIG. 8B. Further, referring to the graphical representation of the surface of the mold 260 shown in FIG. 9A, it can be clearly seen that the surface of the mold 260 of the LED package 200 on which the second plasma process has been performed is relatively even in comparison with FIG. 9B. As a result, a number of coupling sites of the mold 260 made of, e.g., PPA, is greater for the mold 260 according to the exemplary embodiment of the present invention which includes the second plasma process, thereby enhancing adhesion of the protective resin 600 made of, e.g., silicon, to the mold 260. Put another way, the mold 260 and the protective resin 600 of the LED package 200 fabricated utilizing the first plasma process and the second plasma process are firmly adhered to each other. Therefore, a probability that the protective resin 600 will detach from the mold 260 when, e.g., moisture seeps into the mold 260 is substantially reduced. Accordingly, a probability of the first LED chip 420, the second LED chip 430 and/or the third LED chip 440 being damaged is effectively reduced.

In contrast, referring to FIGS. 8B and 9B, a height of the mold of the LED package (not shown) fabricated using a fabrication method which does not include the second plasma process varies substantially, as compared to FIGS. 8A and 9B, according to a location on the surface thereof. Therefore, adhesion of a protective resin to the mold of the LED package is weaker than the adhesion of the protective resin 600 to the mold 260 of the LED package 200 according to the exemplary embodiment of the present invention which includes the second plasma process. Consequently, a probability that the protective resin will detach from the mold may increase, which, in turn, may increase a probability of one or more LED chips being damaged.

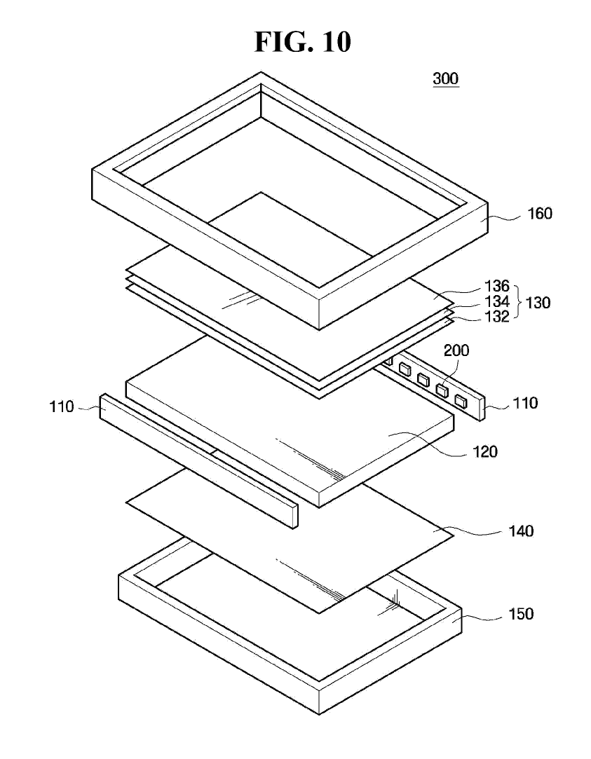

Hereinafter, a backlight assembly according to an exemplary embodiment of the present invention will be described with reference to FIG. 10. FIG. 10 is an exploded perspective view of a backlight assembly according to an exemplary embodiment of the present invention. Both the LED package 200 and the LED package 201 according to exemplary embodiments described in greater detail above can be implemented in the backlight assembly described below, nor are alternative exemplary embodiments limited thereto. However, for purposes of illustration, an exemplary embodiment in which the LED package 200 (best shown in FIG. 1) is implemented in the backlight assembly will be described in further detail.

Referring to FIG. 10, a backlight assembly 300 according to an exemplary embodiment may be an edge-type backlight assembly 300 in which one or more light sources 200 are disposed on a side of a light guide plate 120. In an exemplary embodiment, one or more LED packages 200 are used as the light sources 200. More specifically, the backlight assembly 300 according to an exemplary embodiment includes a plurality of LED packages 200 arranged on an arrangement plate 110. The backlight assembly 300 further includes the light guide plate 120, an optical sheet 130, a reflective sheet 140, a first container 150 and a second container 160.

A longitudinal length of the arrangement plate 110 corresponds to a length of a longitudinal side of the backlight assembly 300, as shown in FIG. 10.

In an exemplary embodiment, the arrangement plate 110 is disposed on one side or, alternatively, two sides of the longitudinal side of the backlight assembly 300, and LED packages 200 of the plurality of LED packages 200 are connected to one another and arranged on the arrangement plate 110. In addition, electrode terminals (not shown) of the LED packages 200 are connected to power supply devices (not shown) disposed on the arrangement plate 110. One or more LED chips (not shown) emitting red, green and/or blue light, for example, are mounted in each of the LED packages 200. The red, green and/or blue light emitted from the LED chips are mixed and are thereby outputted as white light in an exemplary embodiment, but alternative exemplary embodiments of the present invention are not limited thereto.

The light guide plate 120 is a rectilinear plate having substantially flat surfaces thereof, as shown in FIG. 10, and guides an incident light from the LED packages 200 to the optical sheet 130. Specifically, the arrangement plate 110 is disposed substantially parallel to the light guide plate 120 on one side or, alternatively, both sides of the light guide plate 120. Thus, the white light is supplied from the LED packages 200, arranged on the arrangement plate 110, to the light guide plate 120.

In an exemplary embodiment, the light guide plate 120 is made of a light-transmissive material such as polymethyl methacrylate (“PMMA”) and acrylic resin, for example, or, in an alternative exemplary embodiment, a material having a uniform refractive index such as polycarbonate (“PC”).

The optical sheet 130 is disposed on the light guide plate 120 and diffuses and/or collects the white light received from the light guide plate 120. In an exemplary embodiment, the optical sheet 130 includes a diffusion sheet 132, a first prism sheet 134 disposed on the diffusion sheet 132, and a second prism sheet 136 disposed on first prism sheet 134, but alternative exemplary embodiments are not limited thereto.

The reflective sheet 140 is disposed under the light guide plate 120 and has a reflective surface which reflects light emitted from the light guide plate 120 upward.

The first container 150 may be substantially rectilinear and include sidewalls formed along edges thereof. Thus, the arrangement plate 110 having the LED packages 200, the light guide plate 120, the optical sheet 130 and the reflective sheet 140 are accommodated in a space formed within the sidewalls of the first container 150.

Likewise, the second container 160 maybe rectilinear and have sidewalls formed along edges thereof. The second container 160 protects the optical sheet 130 and the light guide plate 200. Since the second container 160 has an aperture, e.g., an opening, disposed at an upper surface thereof, light emitted from the LED packages 200 is transmitted through the aperture. The second container 160 is coupled to the first container 150 to form the backlight assembly 300 according to an exemplary embodiment of the present invention.

The backlight assembly 300 according to an exemplary embodiment includes the LED packages 200, which have good heat resistance and resistance to moisture infiltration. As a result, higher power can be applied to the backlight assembly, while reliability of the backlight assembly is substantially enhanced.

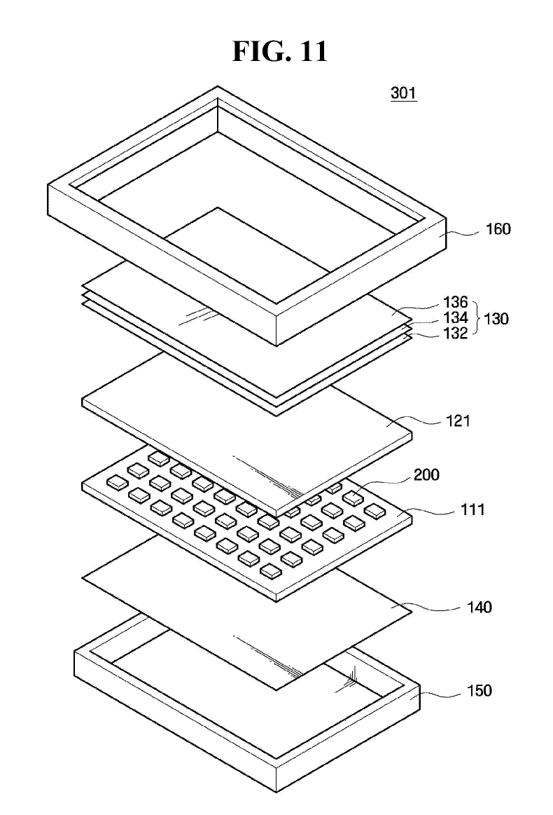

Hereinafter, a backlight assembly according to an alternative exemplary embodiment of the present invention will be described in further detail. FIG. 11 is an exploded perspective view of a backlight assembly according to an alternative exemplary embodiment of the present invention. In FIG. 11, the same reference numerals refer to the same or like components of FIG. 10, and any repetitive detailed description thereof will herein after be omitted.

Referring to FIG. 11, a backlight assembly 301 according to an exemplary embodiment is a direct-type backlight assembly 301 in which one or more light sources 200 are disposed on a lower, e.g., bottom, surface of a first container 150. In an exemplary embodiment, one or more LED packages 200 (see FIG. 1) are used as the light sources 200.

The backlight assembly 301 according to an exemplary embodiment further includes a diffusion plate 121. Further, an arrangement plate 111 including the LED packages 200 is disposed on the bottom surface of the first container 150, as shown in FIG. 11.

The arrangement plate 111 according to an exemplary embodiment may be substantially the same size as the diffusion plate 121, as well as a liquid crystal panel (not shown). Further, the arrangement plate 111 according to an exemplary embodiment is disposed on the bottom surface of the first container 150.

The LED packages 200 are arranged on a first surface of the arrangement plate 111 to form a surface light source. More specifically, the LED packages 200 are arranged at substantially equal intervals in both horizontal and vertical directions, as shown in FIG. 11.

In addition, the diffusion plate 121 is disposed on the arrangement plate 111 including the LED packages 200 arranged thereon. Thus, the diffusion plate 121 enhances a luminance uniformity of light emitted from the LED packages 200.

A reflective sheet 140 is disposed on an opposite second surface of the arrangement plate 111 including the LED packages 200 arranged thereon. Thus, the backlight assembly 301 according to an exemplary embodiment of the present invention as shown in FIG. 11 includes the LED packages 200, which have good thermal resistance, as well as resistance to moisture infiltration, and a higher power can therefore be applied to the backlight assembly, while a reliability thereof is substantially enhanced.

Thus, according to exemplary embodiments of the present invention as described herein, an LED package, a method of fabricating the LED package, and a backlight assembly including the LED package according to exemplary embodiments of the present invention provide at least of the following advantages.

First, one or more protrusions are formed in a mold, thereby substantially reducing a probability that protective resin will slip out of the mold when moisture seeps into the mold.

Second, an LED chip taller than other LED chips is disposed at a center of the mold. Therefore, a probability of disconnection caused by detachment of the protective resin is substantially reduced.

Third, since a number of plasma processes is effectively increased, and the protective resin is therefore more securely adhered to the mold.

The present invention should not be construed as being limited to the exemplary embodiments set forth herein. Rather, these exemplary embodiments are provided so that this disclosure will be thorough and complete and will fully convey the concept of the present invention to those skilled in the art. The exemplary embodiments should be considered in a descriptive sense only and not for purposes of limitation.

While the present invention has been particularly shown and described with reference to exemplary embodiments thereof, it will be understood by those of ordinary skill in the art that various changes in form and detail may be made therein without departing from the spirit or scope of the present invention as defined by the following claims.

What is claimed is:

1. A light emitting diode package comprising:
a mold including an accommodating groove formed therein, the accommodating groove comprising a side surface and a bottom surface;
an electrode pattern disposed on the bottom surface;
a plurality of light emitting diode chips disposed on the electrode pattern; and
protective resin disposed in the accommodating groove, wherein
a center light emitting diode chip of the plurality of light emitting diode chips is disposed at a center of the bottom surface, and
a height of the center light emitting diode chip above the bottom surface is greater than heights of other light emitting diode chips of the plurality of light emitting diode chips above the bottom surface.

2. The light emitting diode package of claim 1, wherein the center light emitting diode chip comprises a vertical electrode type light emitting diode chip.

3. The light emitting diode package of claim 2, wherein the center light emitting diode chip further comprises a red light emitting diode chip.

4. The light emitting diode package of claim 1, further comprising a first protrusion which extends from the side surface toward the center of the bottom surface, wherein
the first protrusion is disposed above the bottom surface by a first gap having a first distance, and
the first protrusion prevents the protective resin from detaching from the mold.

5. The light emitting diode package of claim 4, further comprising a second protrusion which extends from the side surface toward the center of the bottom surface, wherein
the second protrusion is disposed above the bottom surface by a second gap having a second distance different than the first distance, and
the second protrusion prevents the protective resin from detaching from the mold.

6. The light emitting diode package of claim 5, wherein at least one of the first protrusion and the second protrusion is formed contiguous to an inner circumference of the side surface.

7. The light emitting diode package of claim 6, wherein a plane which defines at least one of the first protrusion and the second protrusion is substantially parallel to a plane which defines the bottom surface.

8. The light emitting diode package of claim 5, wherein
at least one of the first protrusion and the second protrusion is divided into a plurality of segments each separated by a predetermined distance, and
segments of the plurality of segments are sequentially formed along an inner circumference of the side surface displaced from each other by the predetermined distance.

9. A method of fabricating a light emitting diode package, the method comprising:
forming an accommodating groove in a mold;
forming a bottom surface in the accommodating groove;
forming a side surface in the accommodating groove;
forming an electrode pattern on the bottom surface;
disposing a center light emitting diode chip on the electrode pattern in a center of the bottom surface;
disposing a side light emitting diode chip on the electrode pattern; and
disposing a protective resin in the accommodating groove,
wherein a height of the center light emitting diode chip above the bottom surface is greater than a height of the side light emitting diode chip above the bottom surface.

10. The method of claim 9, wherein at least one of the disposing of the center light emitting diode chip on the electrode pattern and the disposing of the side light emitting diode chip on the electrode pattern comprises:
die-bonding at least one of the center light emitting diode chip and the side light emitting diode chip onto the electrode pattern; and
performing a first plasma process on the accommodating groove.

11. The method of claim 10, further comprising, after the first plasma process:
wire-bonding the at least one of the center light emitting diode chip and the side light emitting diode chip to the electrode pattern; and
performing a second plasma process on the accommodating groove.

12. The method of claim 11, wherein at least one of the performing of the first plasma process and the performing of the second plasma process comprises using an argon gas.

13. The method of claim 9, wherein the center light emitting diode chip comprises a vertical electrode type light emitting diode chip.

14. The method of claim 9, further comprising:
forming a first protrusion extending from the side surface toward the center of the bottom surface, wherein
the first protrusion is disposed above the bottom surface by a first gap having a first distance, and
the first protrusion prevents the protective resin from detaching from the mold.

15. The method of claim 14, further comprising:
forming a second protrusion extending from the side surface toward the center of the bottom surface, wherein
the second protrusion is disposed above the bottom surface by a second gap having a second distance different than the first distance, and
the second protrusion prevents the protective resin from detaching from the mold.

16. A backlight assembly comprising:
a first container;
an arrangement plate disposed in the first container; and
a light emitting diode package disposed on the arrangement plate, the light emitting diode package comprising:
a mold including an accommodating groove formed therein, the accommodating groove comprising a side surface and a bottom surface;
an electrode pattern disposed on the bottom surface;
a plurality of light emitting diode chips disposed on the electrode pattern; and
protective resin disposed in the accommodating groove, wherein
a center light emitting diode chip of the plurality of light emitting diode chips is disposed at a center of the bottom surface, and
a height of the center light emitting diode chip is greater than heights of other light emitting diode chips of the plurality of light emitting diode chips above the bottom surface.

17. The backlight assembly of claim 16, wherein the center light emitting diode chip comprises a vertical electrode type light emitting diode chip.

18. The backlight assembly of claim 17, wherein the center light emitting diode chip further comprises a red light emitting diode chip.

19. The backlight assembly of claim 16, further comprising a first protrusion which extends from the side surface toward the center of the bottom surface, wherein
the first protrusion is disposed above the bottom surface by a first gap having a first distance, and
the first protrusion prevents the protective resin from detaching from the mold.

20. The backlight assembly of claim 19, further comprising a second protrusion which extends from the side surface toward the center of the bottom surface, wherein
the second protrusion is disposed above the bottom surface by a second gap having a second distance different than the first distance, and
the second protrusion prevents the protective resin from detaching from the mold.
